(19) United States
(12) Patent Application Publication
(10) Pub. No.: US 2020/0274206 A1
(43) Pub. Date: Aug. 27, 2020

(54) BATTERY DEVICE

(71) Applicant: HONDA MOTOR CO., LTD., Tokyo (JP)

(72) Inventor: Naoki Maruno, Wako-shi (JP)

(21) Appl. No.: 16/744,338

(22) Filed: Jan. 16, 2020

(30) Foreign Application Priority Data
Feb. 26, 2019 (JP) 2019-032557

(51) Int. Cl. H01M 10/42; G01R 31/3835; G01R 31/392; B60L 58/12; B60L 58/16

(52) U.S. Cl. CPC H01M 10/4257; G01R 31/3835; H01M 2010/4278; B60L 58/12; B60L 58/16; G01R 31/392

(57) ABSTRACT

A battery device includes a power storage unit, a signal input/output unit to which a security signal is input, a memory unit that stores information indicating a state of the power storage unit, and a switching unit that enables or disables reading of information of the memory unit from outside according to a signal input to the signal input/output unit, and, when a release signal that is one type of the security signal is input to the signal input/output unit, the switching enables reading of the information of the memory unit from outside.

### CROSS-REFERENCE TO RELATED APPLICATION

Priority is claimed on Japanese Patent Application No. 2019-032557, filed Feb. 26, 2019, the content of which is incorporated herein by reference.

### BACKGROUND OF THE INVENTION

### Field of the Invention

The present invention relates to a battery device.

### Description of Related Art

Batteries (secondary batteries) such as lithium-ion batteries are used in electric vehicles such as electric cars and hybrid cars. In order to ensure a stable supply of batteries in the future, it is thought that it will be effective to actively utilize such secondary battery use. In the past, a technology for a device and a method for providing energy management and maintenance of batteries for secondary use by using a secondary service port was disclosed (e.g., refer to Japanese Unexamined Patent Application, First Publication No. 2013-243913).

### SUMMARY OF THE INVENTION

In secondary use of a battery, however, although battery history information is important information and is not supposed to be unlimitedly disclosed, the battery history information has not been fully protected with respect to the related art.

An objective of the present invention has been realized in consideration of such circumstances and is to provide battery history information necessary for secondary use of a battery device to a secondary user with ensured security.

To solve the above-described problem and achieve the objective, the present invention employs the following aspects.

(1) A battery device according to an aspect of the present invention includes a power storage unit, a signal input/output unit to which a security signal is input, a memory unit that stores information indicating a state of the power storage unit, and a switching unit that enables or disables reading of information of the memory unit from outside according to a signal input to the signal input/output unit.

(2) According to the aspect (1), when a release signal that is one type of the security signal is input to the signal input/output unit, the switching unit may enable reading of the information of the memory unit from outside.

(3) According to the aspect (1) or (2), the information of the memory unit includes charge information and a degree of deterioration indicating a degree of deterioration of the power storage unit, the charge information includes at least one of an electric power capacity value, an internal resistance value, and information about characteristics of a state of charge (SoC)-open circuit voltage (OCV) curve, and reading of at least one of the electric power capacity value, the internal resistance value, the information about characteristics of the SoC-OCV curve, and the degree of deterioration from outside may be enabled on the basis of the security signal input to the signal input/output unit.

(4) According to the aspect (3), a control unit that estimates the degree of deterioration on the basis of the charge information and causes the degree of deterioration to be stored in the memory unit may be further included, and reading of the degree of deterioration from outside may be enabled on the basis of the security signal input to the signal input/output unit.

(5) According to any one of the aspects (1) to (4), when a release signal that is one type of the security signal is input to the signal input/output unit, the switching unit may enable an electrical connection of the power storage unit to an electric power input/output terminal.

(6) According to any one of the aspects (1) to (5), a wireless communication unit that receives a radio signal including the security signal may be further included.

According to the aspects (1) to (6), battery history information necessary for secondary use of the battery device can be provided to a secondary user with ensured security.

### BRIEF DESCRIPTION OF THE DRAWINGS

FIG. 1 is a diagram illustrating an example of a configuration of a vehicle 10 in which a battery device 40 according to a first embodiment of the present invention is mounted.

FIG. 2 is a configuration diagram of the battery device 40 according to the first embodiment of the present invention.

FIG. 3 is a configuration diagram of a battery management system 1 within a facility operated by an automobile manufacturer or the like according to the first embodiment of the present invention.

FIG. 4 is a configuration diagram of a battery device 40a according to a third embodiment of the present invention.

FIG. 5 is a configuration diagram of a battery device 40b according to a fourth embodiment of the present invention.

FIG. 6 is a configuration diagram of a battery device 40c according to a fifth embodiment of the present invention.

FIG. 7 is a configuration diagram of a battery control system 2 according to the fifth embodiment of the present invention.

FIG. 8 is a configuration diagram of a battery device 40d according to a sixth embodiment of the present invention.

FIG. 9 is a configuration diagram of a battery device 40e according to a seventh embodiment of the present invention.

### DETAILED DESCRIPTION OF THE INVENTION

Embodiments of a battery device of the present invention will be described below with reference to the drawings.

### First Embodiment

### <Vehicle>

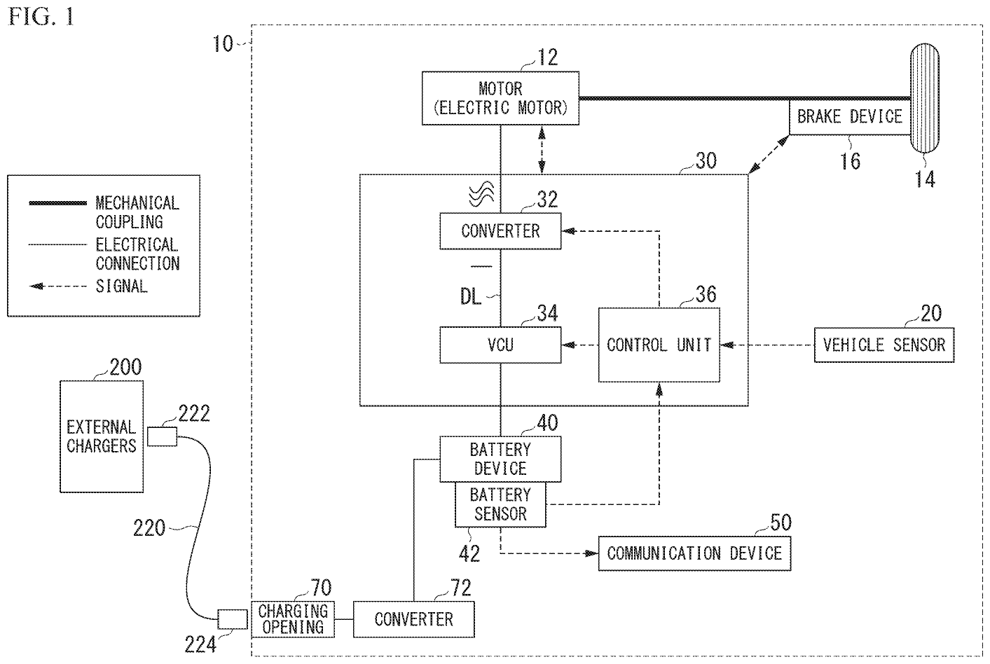

FIG. 1 is a diagram illustrating an example of a configuration of a vehicle 10 in which a battery device 40 is mounted. The vehicle 10 includes, for example, a motor 12, a drive wheel 14, a brake device 16, a vehicle sensor 20, a power control unit (PCU) 30, a battery device 40, a battery sensor 42 including a voltage sensor, a current sensor, a temperature sensor, and the like, a communication device 50, a charging opening 70, and a converter 72 as illustrated in FIG. 1.

The motor 12 is, for example, a three-phase AC electric motor. A rotor of the motor 12 is coupled to the drive wheel 14. The motor 12 outputs power to the drive wheel 14 using supplied electric power. In addition, the motor 12 generates power using kinetic energy of the vehicle during deceleration of the vehicle.

The brake device 16 includes, for example, a brake caliper, a cylinder that transmits hydraulic pressure to the brake caliper, and an electric motor that generates hydraulic pressure in the cylinder. The brake device 16 may include a mechanism that transmits hydraulic pressure generated by an operation of the brake pedal to the cylinder via a master cylinder as a backup. Further, the brake device 16 is not limited to the above-described configuration and may be an electronically controlled hydraulic brake device that transmits hydraulic pressure of the master cylinder to the cylinder.

The vehicle sensor 20 includes an acceleration opening sensor, a vehicle speed sensor, and a brake depression amount sensor. The acceleration opening sensor is attached to the acceleration pedal that is an example of an operator that receives an acceleration instruction from the driver, detects an operation amount of the acceleration pedal, and outputs the operation amount to a control unit 36 as an accelerator opening. The vehicle speed sensor includes, for example, a wheel speed sensor and a speed calculator attached to each wheel, derives a speed of the vehicle (vehicle speed) by combining the wheel speeds detected by the wheel speed sensors, and outputs the result to the control unit 36. The brake depression amount sensor is attached to the brake pedal, detects an operation amount of the brake pedal, and outputs the operation amount to the control unit 36 as a brake depression amount.

The PCU 30 includes, for example, a converter 32, a voltage control unit (VCU) 34, and the control unit 36. The converter 32 is, for example, an AC-DC converter. A DC side terminal of the converter 32 is connected to a DC link DL. The battery device 40 is connected to the DC link DL via the VCU 34. The converter 32 converts an AC generated by the motor 12 into a DC and outputs the DC to the DC link DL. The VCU 34 is, for example, a DC-DC converter. The VCU 34 boosts the power supplied from the battery device 40 and outputs the power to the DC link DL.

The control unit 36 includes, for example, a motor control unit, a brake control unit, and a battery/VCU control unit. The motor control unit, the brake control unit, and the battery/VCU control unit may each be replaced with separate control devices such as, for example, control devices such as a motor ECU, a brake ECU, and a battery ECU. The control unit 36 controls operations of each part of the vehicle 10 such as the converter 32, the VCU 34, and the like.

The control unit 36 is realized by, for example, a hardware processor such as a central processing unit (CPU) executing a program (software). Some or all of these constituent elements may be realized by hardware (a circuit unit: including circuitry) such as a large scale integration (LSI), an application specific integrated circuit (ASIC), a field-programmable gate array (FPGA), or a graphics processing unit (GPU), or may be realized in cooperation of software and hardware.

A program may be stored in advance in a storage device (non-transitory storage medium) such as a hard disk drive (HDD) or a flash memory, stored in a detachable storage medium (non-transitory storage medium) such as a DVD or a CD-ROM, or may be installed by installing a storage medium in a drive device. The control unit 36 selects charge information and estimates a deterioration degree of the battery device 40 by executing a program.

The motor control unit controls the motor 12 on the basis of output of the vehicle sensor 20. The brake control unit controls the brake device 16 on the basis of output of the vehicle sensor 20. The battery/VCU control unit computes a state of charge (SOC) of a power storage unit 420 (which will be described below) of the battery device 40 on the basis of output of the battery sensor 42 attached to the power storage unit 420 of the battery device 40 and outputs the result to the VCU 34. The VCU 34 increases a voltage of the DC link DL according to an instruction from the battery/VCU control unit. Details of the battery device 40 will be described below.

The battery sensor 42 includes, for example, a current sensor, a voltage sensor, and a temperature sensor.

The battery sensor 42 detects, for example, current values, voltage values, temperatures, and the like for charge and discharge of the power storage unit 420. The battery sensor 42 outputs the detected current values, voltage values, temperatures, and the like to the control unit 36 and the communication device 50. Further, the battery sensor 42 may be accommodated in a housing of the battery device 40 or attached to an outside of the housing.

The communication device 50 includes a wireless module for connecting to a wireless communication network such as a wireless LAN, a cellular network, or the like. The wireless LAN may be a scheme, for example, Wi-Fi (registered trademark), Bluetooth (registered trademark), or Zigbee (registered trademark). The cellular network may use, for example, third-generation mobile communication network (3G), fourth-generation mobile communication network (Long Term Evolution or LTE (registered trademark)), fifth-generation mobile communication network (5G), or the like. The communication device 50 may acquire battery usage information such as the current values, the voltage values, the temperatures, and the like output from the battery sensor 42 and transmit the battery usage information to outside.

The charging opening 70 is provided toward the outside of the body of the vehicle 10. The charging opening 70 is connected to the charger 200 via a charging cable 220. The charging cable 220 includes a first plug 222 and a second plug 224. The first plug 222 is connected to the charger 200, and the second plug 224 is connected to the charging opening 70. Electricity supplied from the charger 200 is supplied to the charging opening 70 via the charging cable 220.

In addition, the charging cable 220 includes a signal cable attached to an electric power cable. The signal cable mediates communication between the vehicle 10 and the charger 200. Thus, each of the first plug 222 and the second plug 224 includes an electric power connector and a signal connector.

The converter 72 is provided between the battery device 40 and the charging opening 70. The converter 72 converts a current introduced from the charger 200 via the charging opening 70, for example, an AC current to a DC current. The converter 72 outputs the converted DC current to the battery device 40.

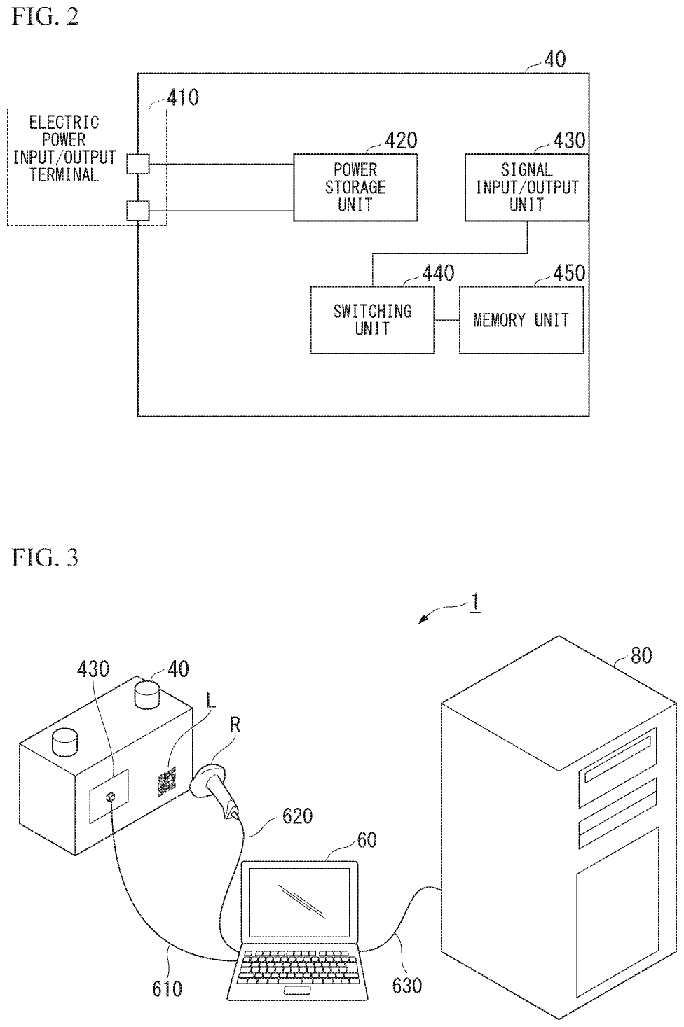

FIG. 2 is a configuration diagram of the battery device 40 according to a first embodiment of the present invention. The battery device 40 of the present embodiment includes, for example, an electric power input/output terminal 410, the power storage unit 420, a signal input/output unit 430, a switching unit 440, and a memory unit 450. These constituent elements are accommodated in one housing.

The battery device 40 is connected to the electric power system of the vehicle via the electric power input/output terminal 410. The power storage unit 420 stores electric power introduced from the charger 200 outside the vehicle 10 and performs discharge for traveling of the vehicle 10. The power storage unit 420 is, for example, a lithium-ion battery, an all solid-state battery, or the like. The power storage unit 420 may be a battery pack in which battery cells are integrated. The signal input/output unit 430 is connected to the control unit 36 of the vehicle. The signal input/output unit 430 includes, for example, a signal terminal (connector) to which a plug or the like is connected. The signal input/output unit 430 receives a security signal. The signal input/output unit 430 is connected to the memory unit 450 via the switching unit 440.

The memory unit 450 may be a memory (non-transitory storage medium) such as a hard disk drive (HDD) or a flash memory, and may further include a control circuit that enables or disables writing of information to the memory or reading of information from the memory, in addition to the memory such as an HDD or a flash memory.

Here, a writing operation by the control unit 36 will be described. The control unit 36 generates, as charge information of the battery device 40, charge information such as an internal resistance value, characteristics of a state of charge (SOC)-open circuit voltage (OCV) curve, a full charge capacity, an ambient temperature of the battery device 40, and the like on the basis of current values, voltage values, temperatures, and the like detected by the battery sensor 42, and writes the charge information to the memory unit 450. Here full charge is assumed to be a state in which, in a predetermined period, the power storage unit 420 is charged to a maximum capacity. The control unit 36 may perform generation of the charge information of the battery device 40 and writing thereof to the memory unit 450 at predetermined time intervals, for example, every one minute, every one hour, or every day, or on the basis of an instruction of a user of the vehicle 10.

In addition, the control unit 36 may estimate a degree of deterioration of the battery device 40 on the basis of the current values, the voltage values, the temperatures, and the like detected by the battery sensor 42 and write the degree of deterioration to the memory unit 450 inside the battery device 40. A degree of deterioration the battery device 40 may be estimated for, for example, a battery capacity. A degree of deterioration of the battery device 40 may be an index indicating a quantitative decrease in a charge capacity of the battery device 40 when the power storage unit 420 inside the battery device 40 is fully charged from the charge capacity of the battery device 40 when the battery device was brand-new.

Alternatively, a degree of deterioration may be an index indicating a quantitative decrease of a charge capacity of the battery device 40 when the battery device 40 is fully charged from a charge capacity of the battery device 40 when the battery device 40 was fully charged at a predetermined time in the past. The control unit 36 estimates a degree of deterioration of the battery device 40 using a known method. The known method may be, for example, a current integration method in which current values included in charge information are integrated as time passes.

The control unit 36 may compute a resistance value in a least squares method sequentially from current values or voltage values included in charge information. The control unit 36 may estimate a battery capacity from AAh/ASOC by predicting an SoC on the basis of the computed resistance value. The control unit 36 may compute a degree of deterioration of the battery device 40 by dividing the estimated battery capacity by the battery capacity in a state of the battery device with no deterioration.

In addition, the control unit 36 may calculate the number of charge cycles of the battery device 40 and write the result to the memory unit 450 inside the battery device 40. Here, the number of charge cycles is assumed to be the number of charging operations of the battery device 40 from a state in which an SoC thereof is lower than a first threshold to a state in which an SoC is equal to or higher than a second threshold in a predetermined period. The first threshold is lower than the second threshold (first threshold<second threshold).

In addition, the control unit 36 may write, to the memory unit 450, a time during which a state of the power storage unit 420 having a charge capacity equal to or higher than a predetermined ratio or lower than a predetermined ratio continues. For example, the control unit 36 may write, to the memory unit 450, a time during which a state in which the power storage unit 420 was charged to 90% or more of the charge capacity continued. Alternatively, the control unit 36 may write, to the memory unit 450, a time during which a state in which the power storage unit 420 was charged to only 10% of the charge capacity continues.

In addition, the control unit 36 may write, to the memory unit 450, a time during which the battery device 40 was continuously used at a temperature equal to or higher than a predetermined ambient temperature or lower than a predetermined ambient temperature. For example, the control unit 36 may write, to the memory unit 450, a time during which the battery device 40 was continuously used at a temperature of 50° C. or higher, or may write, to the memory unit 450, a time during which the battery device 40 was continuously used at a temperature of 0° C. or lower.

The switching unit 440 includes a control section, for example, an integrated circuit (IC) that interprets details of a security signal input to the signal input/output unit 430. The control section enables or disables reading of information stored in the memory unit 450 from outside. The control section operates at all times by receiving supply of weak electric power from the power storage unit 420.

The control section of the switching unit 440 enables reading of information stored in the memory unit 450 from outside when, for example, the security signal input to the signal input/output unit 430 is an enable signal (release signal). Accordingly, the switching unit 440 does not enable reading of the information stored in the memory unit 450 from outside as long as the signal input/output unit 430 does not receive a security signal including the enable signal (release signal), and thus when the battery device 40 is removed from the vehicle 10 and secondarily used, information necessary for use of the battery device 40 can be provided only when appropriate use of the battery device 40 is guaranteed to some extent.

In addition, the security signal that the signal input/output unit 430 receives may include a disable signal (invalidation signal). The disable signal (invalidation signal) is a signal for disabling reading of information stored in the memory unit 450 from outside. Further, the switching unit 440 may enable or disable writing as well as enabling and disabling reading.

The control section of the switching unit 440 may output, to a control circuit included in the memory unit 450, a command to enable or disable reading of information from the memory unit 450. In this case, the control circuit retains a state in which reading is enabled or disabled in itself. In addition, the control section of the switching unit 440 may block a command of reading from the memory unit 450 by itself on the basis of a security signal from the signal input/output unit 430.

The control section of the switching unit 440 may have an internal memory storing predetermined identification information, may control the memory unit 450 when identification information included in a security signal matches the identification information stored in the internal memory, and may not control the memory unit 450 when the identification information does not match. “Match” may include that the two pieces of the information exactly match in terms of details, partially match, can be combined to decrypt encrypted information, and the like. The control section of the switching unit 440 will be assumed to require matching of identification information hereinbelow.

Information stored in the memory unit 450 includes an electric power capacity value of the power storage unit 420, an internal resistance value of the power storage unit 420, information about characteristics of an SoC-OCV curve of the power storage unit 420, the number of charge cycles, a time during which a state of the power storage unit 420 having a charge capacity equal to or higher than a predetermined ratio continued, a time during which a state of the power storage unit 420 having a charge capacity lower than or equal to a predetermined ratio continued, a time during which the battery device 40 was continuously used at a temperature equal to or higher than a predetermined ambient temperature, a time during which the battery device 40 was continuously used at a temperature lower than or equal to a predetermined ambient temperature, and the like. The above-described information is the target to be read from the memory unit 450.

An example of a scene in which the battery device 40 is secondarily used will be described below. FIG. 3 is a configuration diagram of a battery management system 1 within a facility operated by an automobile manufacturer or the like. The battery management system 1 includes the battery device 40, an administrator terminal device 60, and an administrator server device 80. The battery device 40 is removed from the vehicle 10 and used to supply power to a device, an apparatus, or the like separate from the vehicle 10. The battery device 40 may be used as, for example, an emergency power supply device for a blackout or the like in addition to a home appliance, a portable lighting device used in the outdoors, or the like, and a device or an apparatus to which the battery device 40 supplies power is not limited thereto.

The administrator terminal device 60 is connected to the battery device 40 via a wired communication medium 610. A reader/writer R is connected to the administrator terminal device 60 via another wired communication medium 620.

In addition, the administrator terminal device 60 is connected to the administrator server device 80 via another wired communication medium 630. Identification information is stored by, for example, the administrator server device 80 of the automobile manufacturer or the like. The wired communication medium may be, for example, an unshielded twisted pair (UTP) cable or a Universal Serial Bus (USB) (registered trademark) cable.

Code information L, for example, a serial number, a QR Code (registered trademark), or the like is given to an exterior part of the battery device 40 by means of printing, attaching a sticker, stamping, or the like. In a facility operated by an administrator, the serial number can be input to the battery device 40 from the administrator terminal device 60 by using the reader/writer R. In addition, in the facility, the QR Code can be read from the battery device 40 and thus encoded data can be acquired. The administrator terminal device 60 is, for example, connected to the signal input/output unit 430 of the battery device 40. In addition, the administrator terminal device 60 is a device that can communicate with the administrator server device 80.

Upon acquiring the above-described data from the administrator terminal device 60, the administrator server device 80 returns identification information to the administrator terminal device 60. The administrator terminal device 60 inputs the identification information acquired from the administrator server device 80 to the signal input/output unit 430 of the battery device 40 as a security signal. The control section of the switching unit 440 enables reading of the information stored in the memory unit 450 from outside when, for example, the identification information input to the signal input/output unit 430 matches the battery device 40's own identification information.

Here, when a secondary use apparatus controls the battery device 40 without considering a state of the battery, deterioration of the power storage unit 420 of the battery device 40 may progress rapidly. Therefore, when the battery device 40 is removed from the vehicle 10 and secondarily used, appropriate use for the secondary use can be guaranteed to some extent by enabling the secondary use in consideration of the charge information of the battery device 40.

According to the battery device 40 and the battery management system 1 of the above-described first embodiment, battery history information necessary for secondary use of the battery device 40 can be provided to a secondary user with ensured security.

### Second Embodiment

Next, processes according to a second embodiment will be described with reference to FIGS. 1 to 3 focusing on differences from the first embodiment. In the second embodiment, a security signal input to the signal input/output unit 430 from outside includes information about attributes of a user who secondarily uses the battery device 40. The information indicating attributes of the user may indicate that, for example, the user is a used car sales agency, the user is an automobile parts dealer, or the user is a general consumer, not a corporate.

In the second embodiment, the switching unit 440 determines information that enables reading of the memory unit 450 from outside according to the information about attributes of the user. For example, when the information about attributes of the user indicates a used car sales agency or an automobile parts dealer, the switching unit 440 may enable a degree of deterioration of the battery device 40 to be read from the memory unit 450 or enable other charge information of the battery device 40 to be read from the memory unit 450, in addition to a degree of deterioration thereof.

Other charge information mentioned here may be at least one of, for example, an electric power capacity value of the power storage unit 420 included in the battery device 40, an internal resistance value of the power storage unit 420, information about characteristics of an SoC-OCV curve, the number of charge cycles, a time during which a state of the power storage unit 420 having a charge capacity equal to or higher than a predetermined ratio continued, a time during which a state of the power storage unit 420 having a charge capacity lower than or equal to a predetermined ratio continued, a time during which the battery device 40 was continuously used at a temperature equal to or higher than a predetermined ambient temperature, a time during which the battery device 40 was continuously used at a temperature lower than or equal to a predetermined ambient temperature, and the like.

Alternatively, without enabling a degree of deterioration of the battery device 40 to be read from the memory unit 450, the switching unit 440 may enable, for example at least one of the electric power capacity value of the power storage unit 420 included in the battery device 40, the internal resistance value of the battery device 40, the information about characteristics of an SoC-OCV curve, the number of charge cycles, the time during which the state of the power storage unit 420 having a charge capacity equal to or higher than the predetermined ratio continued, the time during which the state of the power storage unit 420 having a charge capacity lower than the predetermined ratio continued, the time during which the battery device 40 was continuously used at a temperature equal to or higher than the predetermined ambient temperature, the time during which the battery device 40 was continuously used at a temperature lower than or equal to the predetermined ambient temperature, and the like to be read.

In addition, when the information about attributes of the user indicates a general consumer, not a corporate, for example, only the electric power capacity value of the power storage unit 420 included in the battery device 40 may be enabled to be read.

Accordingly, since the switching unit 440 can appropriately enable or disable the information to be read from the memory unit 450 according to the information about attributes of the user, when the battery device 40 is removed from the vehicle 10 and secondarily used, the information necessary for the secondary use can be provided to the secondary user with ensured security.

### Third Embodiment

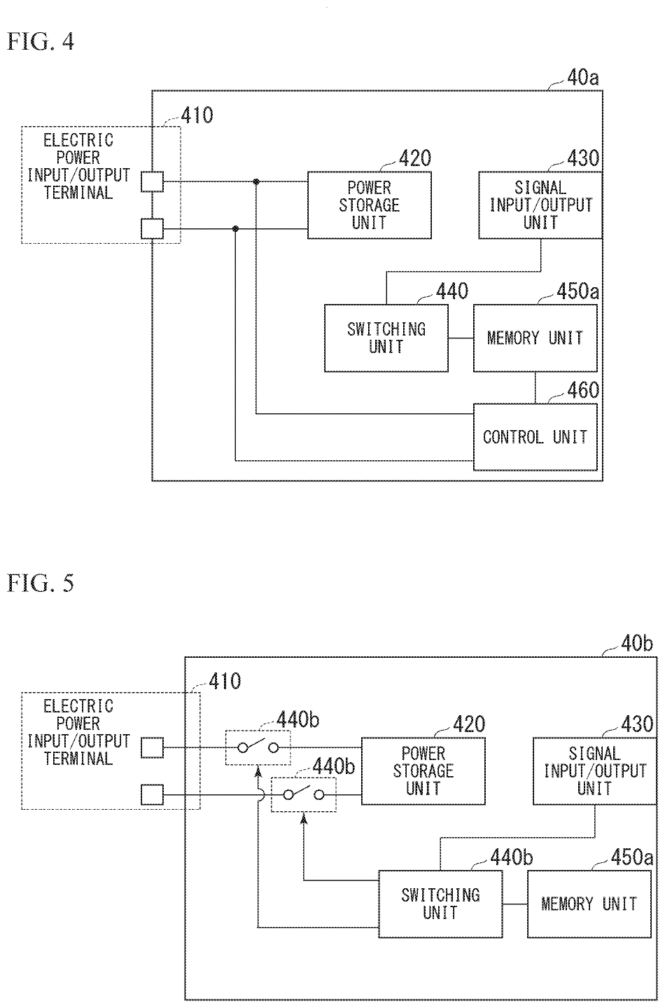

Next, a third embodiment will be described. FIG. 4 is a configuration diagram of a battery device 40a according to the third embodiment of the present invention. The battery device 40a further includes a control unit 460 as illustrated in FIG. 4, unlike the battery device 40 of the first embodiment. The control unit 460 is connected to a power storage unit 420 and a memory unit 450a. The control unit 460 has a built-in sensor, and the sensor has a similar function to that of the battery sensor 42 included in the vehicle 10. The sensor built in the control unit 460 detects, for example, current values, voltage values, and temperatures at which the power storage unit 420 charges and discharges, information about characteristics of an SoC-OCV curve, and the like.

Functions of the control unit 460 are similar to those of the control unit 36 included in the vehicle 10, and a difference between the first embodiment and the second embodiment is that the functions of the control unit 36 are included in the battery device 40a. Therefore, description of operations of the control unit 460 will be omitted. The control unit 460 may estimate a degree of deterioration on the basis of current values, voltage values, temperatures, and the like detected by built-in sensors of the control unit 460 and write the result to the memory unit 450a, similarly to the control unit 36.

Accordingly, when the battery device 40a is removed from the vehicle 10 and secondarily used, history information necessary for secondary use of the battery device 40a can be provided to a secondary user with ensured security only if appropriate use of the battery device 40a is guaranteed to some extent. In addition, even when the battery device 40a is removed from the vehicle 10, a battery use history can be continuously recorded in the memory unit 450a by using the control unit 460 built in the battery device 40a. In addition, information stored in the memory unit 450a can be protected from being read from outside even if the battery device 40a could be subjected to unnecessary secondary use when the battery device is removed from the vehicle 10 and secondarily used.

### Fourth Embodiment

A battery device 40b according to a fourth embodiment of the present invention will be described using FIG. 5. Processes according to the fourth embodiment will be described focusing on differences from the first to the third embodiments. FIG. 5 is a configuration diagram of the battery device 40b according to the fourth embodiment of the present invention. The battery device 40b of the fourth embodiment includes switching units 440b. The switching units 440b has a difference from those of the first to the third embodiments in that a contactor that enables or disables an electrical connection of the power storage unit 420 to the electric power input/output terminal 410 is included. The contactor may be provided between the entire power storage unit 420 and the electric power input/output terminal 410 or may be provided for each battery cell.

A control section of each switching unit 440b enables reading of information stored in a memory unit 450b from outside and at the same time enables an electrical connection of the power storage unit 420 to the electric power input/output terminal 410 when, for example, a security signal input to the signal input/output unit 430 is an enable signal (release signal). In addition, the switching units 440b may be in a state of disabling reading of information stored in the memory unit 450b from outside and at the same time disabling an electrical connection of the power storage unit 420 to the electric power input/output terminal 410 when a security signal input to the signal input/output unit 430 is a disable signal (invalidation signal).

Accordingly, when the battery device 40b is removed from the vehicle 10 and secondarily used, the secondary use is possible on the basis of the security signal input to the signal input/output unit 430, and history information necessary for secondary user of the battery device 40b can be selectively provided to a secondary user with ensured security while appropriate use during the secondary use is guaranteed to some extent.

### Fifth Embodiment

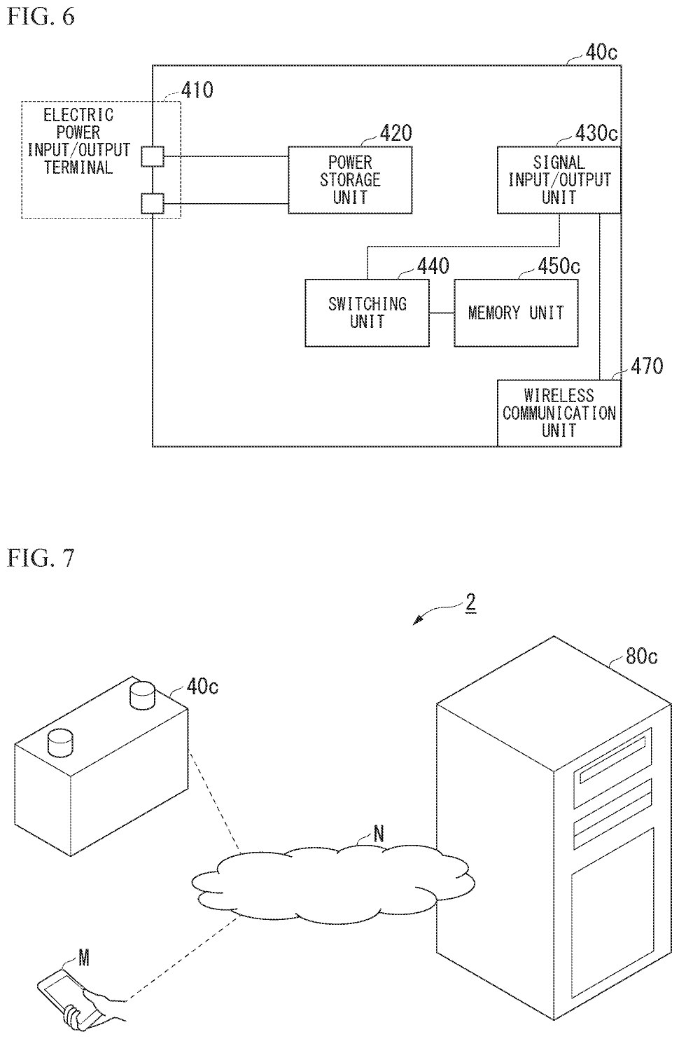

A battery device 40c according to a fifth embodiment of the present invention will be described below using FIGS. 6 and 7. Processes according to the fifth embodiment will be described focusing on differences from the first to the fourth embodiments. FIG. 6 is a configuration diagram of the battery device 40c according to the fifth embodiment. The battery device 40c further includes a wireless communication unit 470, unlike the battery device 40 of the first embodiment. The wireless communication unit 470 transmits and/or receives radio signals via a wireless communication network N. In addition, the wireless communication unit 470 can receive a security signal in a radio signal. The wireless communication unit 470 outputs the received security signal to a signal input/output unit 430c. Subsequent processes are similar to those of the first and the second embodiments.

Next, an example of a scene in which the battery device 40c is secondarily used will be described. FIG. 7 is a configuration diagram of a battery control system 2 according to the fifth embodiment of the present invention. In the battery control system 2, the battery device 40c may be removed from the vehicle 10 and used to supply power to a device, an apparatus, or the like separate from the vehicle 10. The battery device 40c is connected to a wireless communication terminal M via the wireless communication network N. An administrator server device 80c may be connected to the wireless communication network N.

The wireless communication network N may be constructed within a facility operated by an automobile manufacturer and may be a wireless communication network such as Wi-Fi (registered trademark) or Bluetooth (registered trademark). Within a facility operated by an automobile manufacturer, for example, only when the battery device 40c is connected to the wireless communication network N and authenticated by the administrator server device 80c, an employee of the automobile manufacturer operates the wireless communication terminal M and thereby can remotely operate the battery device 40c through the wireless communication network N.

Accordingly, since the switching unit 440 does not enable reading of information stored in a memory unit 450c from outside unless the battery device 40c is connected to the wireless communication network N and authenticated by the administrator server device 80c and the signal input/output unit 430c receives a security signal, even when the battery device 40c is removed from the vehicle 10 and secondarily used, history information of the battery device 40c can be provided to a secondary user with ensured security while appropriate use of the battery device 40c can be guaranteed to some extent.

In addition, when a security signal is input to the wireless communication unit 470 in a radio signal, the battery device 40c may not be connected to the wireless communication network N. As long as a user is within the facility operated by the automobile manufacturer, for example, the user may include a security signal in an RF tag and input the security signal to the wireless communication unit 470 through non-contact near field wireless communication. Accordingly, even when the battery device 40c is removed from the vehicle 10 and secondarily used, the history information of the battery device 40c can be provided to the secondary user with ensured security while appropriate use of the battery device 40c can be guaranteed to some extent.

### Sixth Embodiment

Further, the above-described embodiments may be appropriately combined. An operation of a battery device 40d according to a sixth embodiment will be described. For example, the battery device 40c of the battery control system 2 illustrated in FIG. 7 may be replaced with the battery device 40d.

Processes according to the sixth embodiment will be described focusing on differences from the third embodiment.

FIG. 8 illustrates a configuration diagram of the battery device 40d according to the sixth embodiment. The battery device 40d further includes a wireless communication unit 470d, unlike the battery device 40a of the third embodiment. The wireless communication unit 470d receives a radio signal including a security signal. The wireless communication unit 470d outputs the security signal to a signal input/output unit 430d. Subsequent processes are similar to those of the third embodiment.

Accordingly, when the battery device 40d is removed from the vehicle 10 and secondarily used, the secondary use is possible on the basis of the security signal input to the wireless communication unit 470d, and thus appropriate use during the secondary use can be guaranteed to some extent. Besides, history information of the battery device 40d can be provided to the secondary user with ensured security. In addition, even when the battery device 40d is removed from the vehicle 10, a battery use history can be continuously recorded in a memory unit 450d by using the control unit 460 built in the battery device 40d.

### Seventh Embodiment

Further, the above-described embodiments may be appropriately combined. An operation of a battery device 40e according to a seventh embodiment will be described. For example, the battery device 40b according to the fourth embodiment can be applied to the battery control system 2 according to the fifth embodiment. For example, the battery device 40c of the battery control system 2 illustrated in FIG. 7 may be replaced with the battery device 40e.

Processes according to the seventh embodiment will be described focusing on differences from the fourth embodiment.

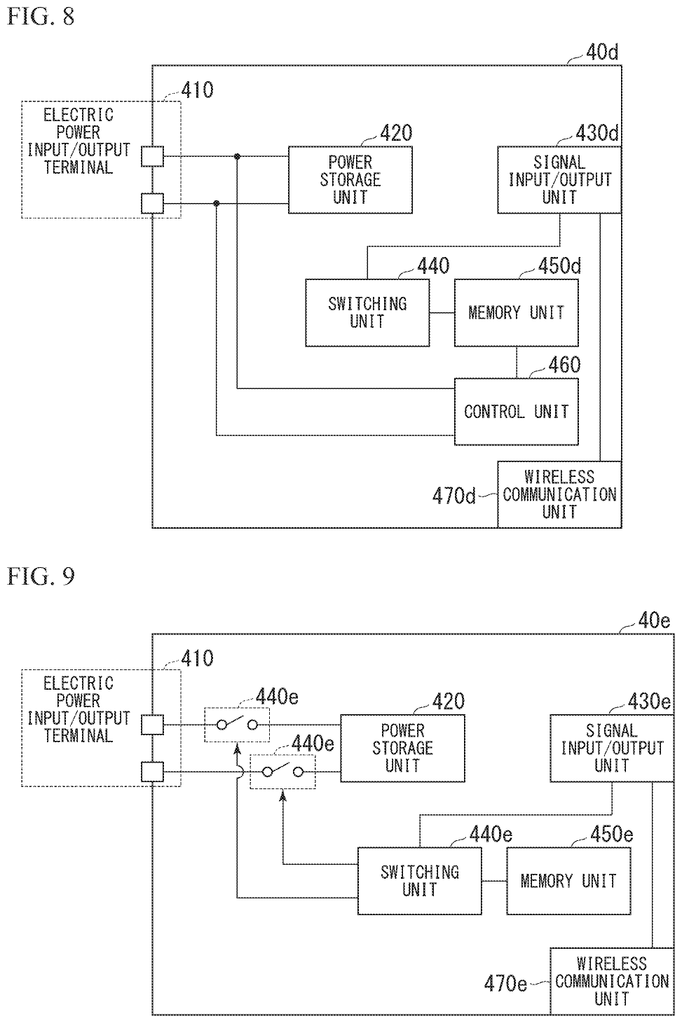

FIG. 9 illustrates a configuration diagram of the battery device 40e according to the seventh embodiment. The battery device 40e further includes a wireless communication unit 470e, unlike the battery device 40b of the fourth embodiment. The wireless communication unit 470e receives a radio signal including a security signal. The wireless communication unit 470e outputs the security signal to a signal input/output unit 430e. Subsequent processes are similar to those of the fourth embodiment.

Accordingly, when the battery device 40e is removed from the vehicle 10 and secondarily used, the secondary use is possible on the basis of the security signal input to the wireless communication unit 470e, and thus appropriate use during the secondary use can be guaranteed to some extent. Moreover, history information of the battery device 40e can be provided to a secondary user with ensured security.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description and is only limited by the scope of the appended claims.

What is claimed is:

1. A battery device comprising:
a power storage unit;
a signal input/output unit to which a security signal is input;
a memory unit configured to store information indicating a state of the power storage unit; and
a switching unit configured to enable or disable reading of information of the memory unit from outside according to a signal input to the signal input/output unit.

2. The battery device according to claim 1,
wherein, when a release signal that is one type of the security signal is input to the signal input/output unit, the switching unit enables reading of the information of the memory unit from outside.

3. The battery device according to claim 1,
wherein the information of the memory unit includes charge information and a degree of deterioration indicating a degree of deterioration of the power storage unit,
wherein the charge information includes at least one of an electric power capacity value, an internal resistance value, and information about characteristics of a state of charge (SoC)-open circuit voltage (OCV) curve, and
wherein reading of at least one of the electric power capacity value, the internal resistance value, the information about characteristics of the SoC-OCV curve, and the degree of deterioration from outside is enabled on the basis of the security signal input to the signal input/output unit.

4. The battery device according to claim 3, further comprising:
a control unit configured to estimate the degree of deterioration on the basis of the charge information and cause the degree of deterioration to be stored in the memory unit,
wherein reading of the degree of deterioration from outside is enabled on the basis of the security signal input to the signal input/output unit.

5. The battery device according to claim 1,
wherein, when a release signal that is one type of the security signal is input to the signal input/output unit, the switching unit enables an electrical connection of the power storage unit to an electric power input/output terminal.

6. The battery device according to claim 1, further comprising:
a wireless communication unit configured to receive a radio signal including the security signal.
